(19) United States
(12) Patent Application Publication
(10) Pub. No.: US 2023/0198009 A1
(43) Pub. Date: Jun. 22, 2023

(54) METHOD FOR THE MANUFACTURE OF AN ENERGY STORAGE DEVICE UTILIZING LITHIUM AND SOLID INORGANIC ELECTROLYTES

(71) Applicant: Pulsedeon Oy, Tampere (FI)

(72) Inventors: Jari LIIMATAINEN, Tampere (FI); Ville KEKKONEN, Tampere (FI)

(73) Assignee: Pulsedeon Oy, Tampere (FI)

(21) Appl. No.: 17/996,326

(22) PCT Filed: Apr. 15, 2021
(86) PCT No.: PCT/FI2021/050277

§ 371 Date: Oct. 14, 2022

(30) Foreign Application Priority Data
Apr. 17, 2020 (FI) 20207064

(51) Int. Cl. H01M 10/0562; H01M 4/04; H01M 4/38; H01M 10/052

(52) U.S. Cl. CPC H01M 10/0562; H01M 4/382; H01M 4/0404; H01M 4/0423; H01M 10/052; H01M 2004/027

(57) ABSTRACT

A method is for producing electrochemical energy storage devices utilizing lithium and for producing materials used in the devices, such that the anode has lithium metal, inorganic solid electrolytes. Anode and cathode components are joined together by pressure and/or temperature utilized in the production. The lithium-metal layer is produced at least partly by a pulsed laser deposition method. The method can utilise various inorganic solid electrolytes produced by different methods and a roll-to-roll method as well as different ways to couple pressure and/or temperature to the component being processed.

### FIELD OF THE INVENTION

The invention is related to electrochemical energy storage devices utilising lithium such as batteries and capacitors, to their structure, and to manufacturing of materials used in these devices. The invention is especially related to the manufacturing method of at least one lithium-containing component of a lithium battery, a lithium-ion battery or a lithium-ion capacitor, which method utilises various coating methods as well as methods of compaction and joining of materials.

### BACKGROUND OF THE INVENTION

As the need for mobile devices, electrically operated cars and energy storage grows, the need for the development of battery technology has increased. Li-ion batteries have been successful in very many applications, especially due to their good energy density and recharging possibilities compared, among others, to traditional Ni—Cd (Nickel-Cadmium) and Ni—Mn (Nickel-Manganese) batteries.

Today, the widely adapted lithium battery technology is based on a positive electrode (cathode) made from transition metal oxide and on a carbon-based negative electrode (anode). Migration pathway for the Li-ions between the positive and negative electrodes is the electrolyte which in the contemporary solutions mostly is liquid but ways to use solid state electrolytes are being developed actively. Especially in the case of liquid electrolyte, a microporous polymer separator is used between the anode and cathode as an insulator which prevents the contact of the anode and cathode but allows the passage of ions through the separator membrane.

The energy density of Li-ion batteries is defined by the capability of the electrode materials to reversibly store lithium as well as by the amount of lithium available for ion exchange in the battery. When a battery is being used, meaning energy is drawn from or stored in the battery, lithium ions move between the positive and negative electrodes. During usage, chemical and structural changes take place in the electrode materials which can affect the lithium storing capabilities of the materials or the amount of lithium.

When talking about lithium battery one usually means Li-metal battery which has metallic lithium as an anode. The advantage of Li anode is its high energy density, but their use is limited by the uncontrolled growth of so-called Li dendrites i.e., formation of needle-like projections, which can cause short-circuiting of the battery cell because dendrites are able to penetrate the separator membrane and electrically connect the anode and the cathode. This is a major safety risk. Also, lithium is highly reactive, which is why special arrangements in its handling and usage are required in order to avoid the harmful effects of the reaction products. For example, the reactivity easily results in formation of a thick SEI layer on the surface of lithium metal. Furthermore, when lithium metal is used as such, without a supporting framework as an anode, the volume change of the anode can be infinite because the anode does not contain lithium in the discharged state of the battery.

As mentioned previously, the use of Li-metal anodes is partly limited by the risk of dendrite growth from the anode to the cathode, which can cause short-circuiting and damage of the battery, fire, or even an explosion. One way to prevent the growth of dendrites is to use solid electrolytes which can be either inorganic materials or polymers. Inorganic materials are more effective than polymers in preventing the growth of dendrites from the anode to the cathode. Furthermore, the ionic conductivity of polymers at room temperature is not as good as that of the best inorganic electrolytes, such as LPS materials (e.g. Li₇P₃S₁₁, Li_{9.6}P₃S₁₂), and to improve the ionic conductivity it might be necessary to heat up the batteries.

One challenge related to the use of solid electrolytes is to ascertain that the solid electrolyte is distributed on the cathode side such that the movement of ions from the cathode particles is enabled within the whole cathode layer. This means that preferably one should generate a structure with a homogeneous distribution of cathode particles within a matrix of solid electrolyte in which matrix the solid electrolyte forms continuous pathways for the passage of ions. Producing of structure like this is difficult.

An alternative solution is to combine both inorganic solid electrolytes and either polymer solid electrolytes or liquid electrolytes in the same battery concept, in which case it is easier to generate the desired distribution of cathode particles and electrolyte within the cathode material. The challenge related to polymers is their poor ionic conductivity at room temperature as described previously. Certain problems related to liquid electrolytes are their high risk to catch fire or degrade as they age. When compared to inorganic solid electrolytes, an advantage of polymers and liquid electrolytes is their better ability to reduce the mechanical stresses generated by volume changes during charge and discharge of Li-ion battery. On the other hand, also different solid electrolytes vary in their rigidity, i.e. Young’s modulus, and, for example lithium thiophosphates, such as LPS (Li₇P₃S₁₁, Li_{9.6}P₃S₁₂), have significantly lower Young’s modulus than several oxides, such as LLZO. Lower Young’s modulus reduces the generation of stresses during charge and discharge of batteries.

One of the limiting factors related to use of lithium metal is the difficulty to form reliable bonding to other materials. For example, bonding Li metal to the metal-foil current collector such that the contact withstands long-term usage has been found to be challenging.

Various protective coatings could be needed in order to minimise detrimental electrochemical and chemical reactions at the interfaces between different materials, especially those containing lithium, and to minimise the damages in the battery or capacitor materials taking place during the use. Also, the protective coatings might need lithiation in order to function as Li-ion transporters. For example, on the surface of the cathode, one could apply inorganic materials such as ZnO, Al2O3, AlPO4, AlF3, which in their lithium-containing form allow the passage of Li ions but prevent the reaction between the cathode and the electrolyte or prevent the dissolution of the components of the cathode. Solid-state electrolytes, such as Li2.88PO3.73N0.14 (LIPON), Li10GeP2S12 (LGPS), Li9.54Si1.74P1.44S11.7Cl0.3, Li9.6P3S12 (LPS), Li1.3Al0.3Ti1.7 (LATP), LLTO, LLMO (M=Zr, Nb, Ta), can function as protective coatings for electrodes. Especially, the above-mentioned LLMO-type of electrolytes are applicable as mechanically durable protective coatings and supporting frameworks.

The stability of Li-metal anodes at different interfaces varies. For example, the promising solid electrolyte Li7P3S11, Li9.6P3S12 (LPS) has a narrow stability window in contact with Li-metal anode, because of which use of interlayers could be necessary. For example, the electrochemical stabilty window of LLZO has been found to be wide when paired with Li-metal or LPS solid electrolyte.

In order to utilise Li metal, for example, in energy storage applications, one should be able to produce layers of Li metal which have especially the following properties:
Li metal doesn’t contain impurities or detrimental reaction products within the layer or on interfaces.
The layer has good adhesion to various substrate materials.
The amount of Li metal and thickness of the layer can be controlled precisely.
The Li-metal anode is separated from the cathode by at least one layer of solid electrolyte which has sufficient ionic conductivity and the ability to prevent the growth of Li-metal dendrites from the anode to the cathode.
In the cathode material layer, one can utilise inorganic solid electrolyte which has good distribution with cathode particles, and which has sufficient ionic conductivity at room temperature.

### SUMMARY OF THE INVENTION

The present invention discloses a method for producing lithium-containing materials and material layers applied in lithium batteries, Li-ion batteries and Li-ion capacitors where the method utilises laser ablation deposition, solid inorganic electrolytes and mechanical compression at room temperature or at an elevated temperature. The method is applicable for industrial mass production of material layers and coatings. The method enables the utilisation of inorganic solid electrolytes having the best technical properties paired with Li-metal anodes without the use of liquid electrolytes or polymer electrolytes.

In the method of the present invention, a Li-ion battery is produced by utilising two separate components which are finally joined by means of temperature and pressure or combination of the two into a component of a Li-ion battery, in which component a solid electrolyte comprises at least 80% of the total amount of electrolyte.

The first component is an anode comprising a current collector, such as a copper or nickel foil, a layer of Li metal, and a layer of inorganic material which has sufficient ionic conductivity to enable functionality of the battery.

The second component is a cathode comprising a current collector, such as an aluminium foil, and a cathode-material layer in which the cathode particles and inorganic solid electrolyte as well as other necessary constituents, such as components improving electrical conductivity, form a composite such that the solid electrolyte forms essentially continuous pathway for conduction of ions.

On the anode side, the inorganic solid electrolyte should preferably be material which can be deposited by diverse vacuum deposition methods, such as physical vapor deposition (PVD) or chemical vapor deposition (CVD), atomic layer deposition (ALD) or pulsed laser deposition (PLD), and which can be compacted by means of pressure and/or temperature. The layer of active material on the cathode side can be produced also by mixing an inorganic solid electrolyte with cathode particles and other necessary constituents and then combine it with a current collector and an anode component.

Joining the anode and the cathode is realised by means of temperature and/or pressure which both can at the same time be utilised for densifying the anode and the cathode and for improving the internal quality of the components such as the quality of the contacts. The joining can be produced by uniaxial compression or, for example, by rolling the anode and cathode together with or without applying heat.

The inventive idea of the invention also comprises the final product manufactured using the method, i.e., a Li battery, a Li-ion battery, or a Li-ion capacitor, comprising an anode, a cathode, and a solid-electrolyte material, such that at least one layer containing lithium metal or lithium compound is manufactured by laser ablation deposition.

### SHORT DESCRIPTION OF THE DRAWINGS

FIG. 1 illustrates a certain principle of the deposition procedure of Li-metal anode which deposition procedure is based on pulsed laser deposition.

FIG. 2 illustrates the principle of the deposition procedure of an inorganic solid electrolyte on Li-metal which deposition procedure is based on pulsed laser deposition.

FIG. 3 illustrates manufacturing of cathode-material, which manufacturing is based on mixing of cathode-material powder and inorganic solid electrolyte and following compaction of the mixture.

FIG. 4 illustrates coating process of cathode particles with inorganic solid electrolyte.

FIG. 5 illustrates the joining of an anode component and a cathode component by means of pressure and/or temperature.

### DETAILED DESCRIPTION OF THE INVENTION

In the method of the invention, a lithium-containing material layer or a multi-layer structure of a lithium battery, Li-ion battery, or Li-ion capacitor is produced by utilising selected vacuum deposition methods which are utilised for producing material layers which are suited for the method or which gain relative productivity or quality advantages because of the method as well as by utilising mechanical and thermal processing for densifying and joining components.

In the method of the invention, the intention is to utilise a solution based on Li-metal anodes together with inorganic solid electrolytes, cathode materials enabling high energy density, and with protective layers improving the safety, performance, and lifetime of the components.

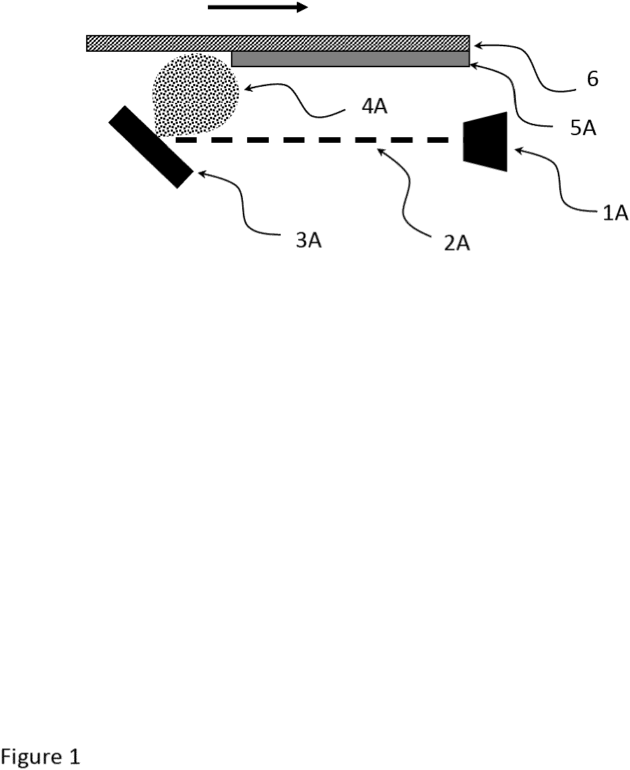

Battery solution of the invention requires advanced processing methods to produce the desired structure and adhesion between different materials. The anode comprises a current collector on top of which the functional material layers are deposited by vacuum deposition methods, such as PVD (for example sputtering), CVD, PLD, ALD, thermal evaporation, or some other suitable method. The current-collector material is typically a 6-20 micrometers thick copper foil, but alternatively any other metal, such as nickel or metal alloy, having sufficient electrical conductivity and chemical stability could be applied. Li metal can be deposited directly on the surface of the current collector taking into account the desired energy density and capacity of the battery. Alternatively, only a thin, so-called seed layer of Li metal can be deposited on the surface of the current collector, which seed layer functions as receiving substrate for the lithium stored by other battery components, such as the cathode. By utilising a seed layer of lithium metal one can promote the homogeneous deposition of lithium on the anode during charging of the battery. Instead of a seed layer of lithium metal one can utilise also a lithiophilic material layer with the intention to promote homogeneous deposition of lithium from other material layers, such as the cathode, on the current collector during charging. FIG. 1 represents in an exemplary manner the deposition of a Li-metal layer 5A on a metal current collector 6 by utilising pulsed laser depostion (PLD). Laser pulses 2A from a laser source 1A are directed to a Li-metal target 3A. A material flow 4A is ejected from the target 3A as result of the energy of the laser pulses 2A, the material flow 4A comprising atomised and ionised particles and molten particulates which together form a lithium-metal coating 5A as they impinge and attach on the current collector 6. In the figure, the metal current collector 6 functioning as the substrate moves from left to right to the direction indicated by the arrow through the material flow 4A, whereupon a lithium-metal coating 5A of a desired thickness and covering a desired surface area can be produced. In other potential methods, such as thermal evaporation, the process-technical arrangement is different.

Especially in the case of lithium metal, it is essential to choose the deposition method such that good adhesion to the current collector can be achieved, detrimental reactions of Li metal with the environment can be prevented, and sufficiently good uniformity of Li-metal layer can be produced. Lithium metal reacts readily especially with moisture in the air, which is why the deposition should be carried out in controlled atmosphere where the water content is 5 ppm at most and most preferably less than 2 ppm. For example, using pulsed laser deposition, it is possible to reach the above-mentioned quality criteria of a good lithium-metal coating.

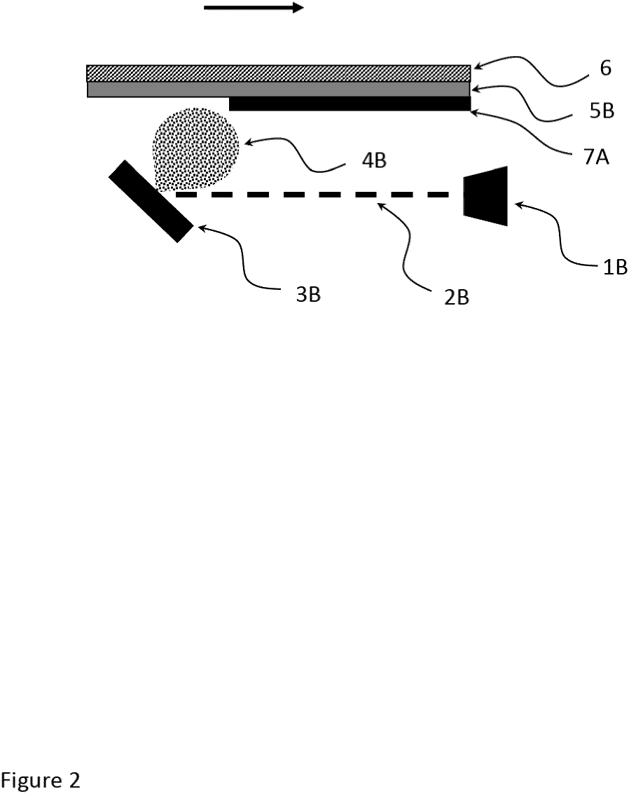

In the subsequent process step, an inorganic material layer is produced on the anode and on the surface of lithium metal, which inorganic material layer preferably has good ionic conductivity, ability to block the growth of dendrites through the layer, and sufficient chemical and electrochemical stability against materials in contact with it. In order to be able to join the anode to the cathode by means of pressure and/or temperature, the adherence of this inorganic material layer on the anode to the contact surface of the cathode should be good enough. The method is illustrated in an exemplary manner based on PLD in FIG. 2, where laser pulses 2B from a laser source 1B are directed to a target 3B. A material flow 4B is generated from the target 3B, which material flow comprises, as previously described in FIG. 1 in the exemplary case of lithium metal layer, atomised and ionised particles and molten particulates which together form a coating 7A on the surface of a lithium coating 5B. Like in FIG. 1, also in FIG. 2, the substrate, which in this case is a metal current collector 6 coated with the lithium-metal layer 5B, moves in the plane of the figure in the direction indicated by the arrow from left to right in order to form a coating of a desired thickness and on a desired surface area.

Particularly advantageous would be using the same material at the contact surfaces of both the anode and the cathode, which contact surfaces are used for joining the components by means of pressure and/or temperature. Especially lithium thiophosphates, such as LPS, are well-suited for this type of joining because of their malleability especially when elevated temperatures are used. If the contact surfaces of both the anode and the cathode components are of the same material, like for example LPS, it is possible to achieve the best quality of the contacts.

One can add also more than one material on the surface of the lithium metal on the anode, if it is necessary for preventing the growth of dendrites, chemical or electrochemical stability, or for guaranteeing sufficient mechanical flexibility or ionic conductivity. A possible realisation is to add first a thin layer of ionically conducting inorganic material having high Young’s modulus, material such as LLZO or LiPON, with thickness of 5 micrometers at most on the surface of the lithium metal, after which a sufficiently thick, however less than 20 micrometers thick, layer of for example lithium thiophosphate, such as LPS. LPS has good ionic conductivity, and its better flexibility allows for reducing the stresses caused by the volume changes related to the charge and discharge of the battery.

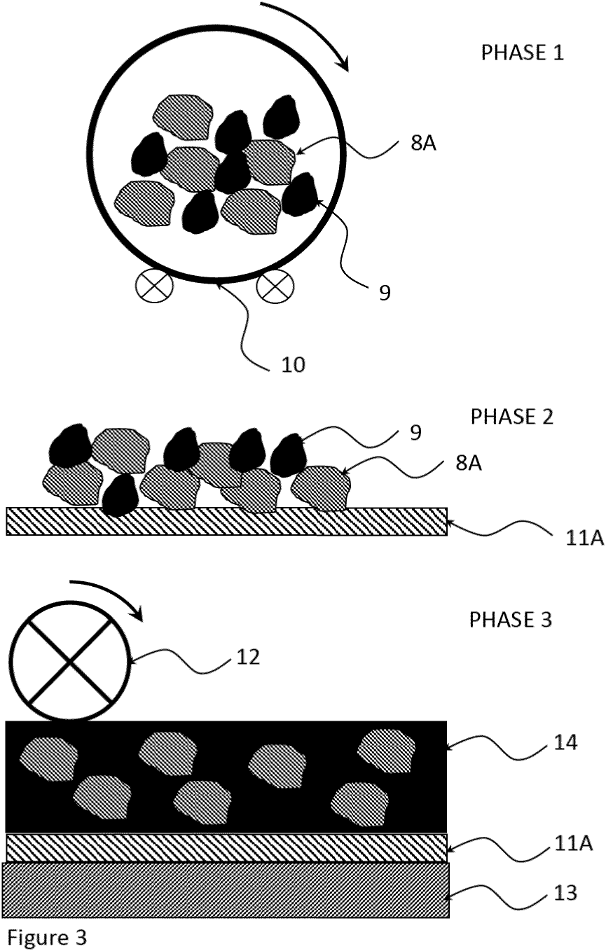

In the manufacture of the cathode, a composite material is attached to the current collector, in which composite material a cathode material providing the desired energy density forms together with an ionically conductive inorganic solid electrolyte a homogeneous cathode material layer. The current collector can be of suitable metal, such as aluminium, but one can also use any other metal which allows adherence of the cathode material and has sufficient chemical and electrochemical stability. An essential feature of the cathode is that mobility of ions from each cathode particle to the anode and back throughout the whole thickness of the cathode layer can be ensured. In order to guarantee the unobstructed movement of the ions, the cathode particles should be homogenously distributed within the inorganic solid electrolyte, and the ionic conductivity of the solid electrolyte should be as good as possible also at room temperature. Equally vital is to guarantee the passage of electrons from each cathode particle to the current collector throughout the whole thickness of the cathode layer. One of the basic properties of the solid electrolyte material is to enable effective passage of ions but to be a poor conductor for electrons. Because of this, it could be necessary to mix electron-conducting material homogeneously distributed into the cathode material layer, such that an electron-conducting network is formed within the part of the layer containing cathode particles. FIG. 3 represents a method to produce a mixture of cathode particles 8A and solid-electrolyte particles 9 in a mixer 10 (Phase 1). The ready mixture is spread onto a current collector 11A (Phase 2), after which the mixture is compacted and attached to the current collector 11A by calendaring using, for example, a roller 12 on a worktable 13 to form a dense mixture 14 of cathode particles 8A and solid electrolyte (Phase 3).

One needs to control the detrimental reactions of the cathode particles with the inorganic solid electrolyte surrounding the particles. This tendency can be reduced by proper selection of materials as well as by coating the cathode particles with suitable thin layer to prevent the unfavorable reactions at the interfaces.

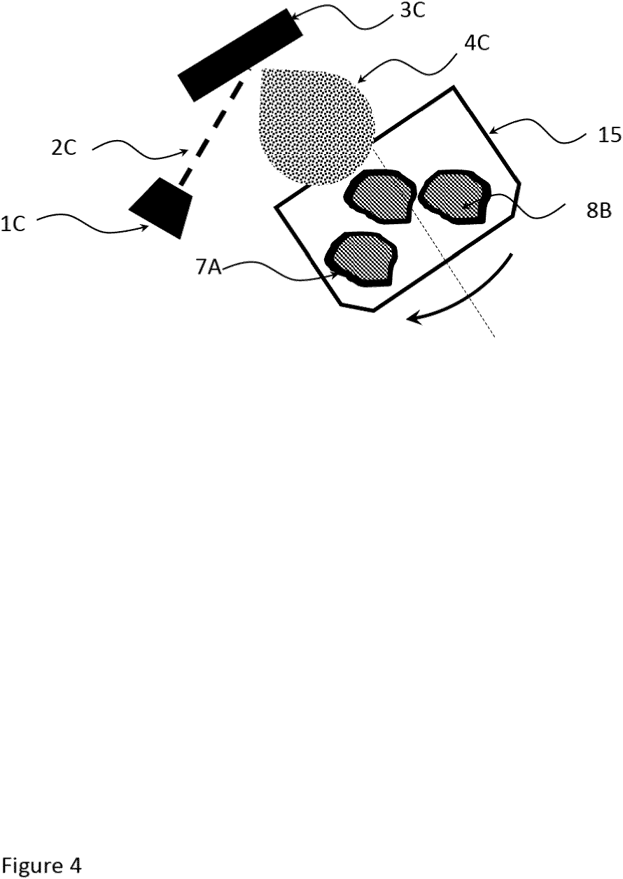

Achieving a suitable distribution of solid electrolyte and cathode particles within the cathode material is important for generating sufficient ionic conductivity throughout the whole cathode layer and thereby guaranteeing the functionality of the battery. This can be realised, for example, by mixing solid-electrolyte powder and cathode particles in the desired ratio and thereafter compacting the powder mixture by means of pressure and/or temperature. Another option is to apply a coating of inorganic solid electrolyte or some other inorganic material on the cathode particles by utilising a suitable coating technology, such as PVD, CVD, ALD, or PLD, and thereafter compacting the coated particles by means of pressure and/or temperature attaching them on the metal current collector at the same time. Other methods, such as thermal spraying or cold spraying, can also be utilised. When selecting the coating and mixing methods it is important to avoid detrimental reaction of the solid electrolyte with the environment especially in the case of sensitive materials such as lithium thiophosphates (e.g., LPS). The coating process of cathode particles is represented in an exemplary manner in the case of utilising PLD in FIG. 4. The coating process can be carried out, for example, in a mixer 15 where cathode particles 8B being mixed are coated with a layer of solid electrolyte 7A by directing laser pulses 2C from a laser source 1C to an inorganic solid-electrolyte target 3C in order to generate a material flow 4C towards the cathode particles 8B being mixed.

When the anode and cathode components have been processed, the next step is to join them together by means of pressure and/or temperature to form cell components for batteries. Considering especially cases where lithium thiophosphates (inter alia LPS or LGPS) are utilised as solid electrolyte and form the contact surfaces of the two components, it is possible to join the materials together reliably even by cold compaction. On the other hand, temperature can promote the densification of materials during pressing or allow for using lower pressure for compaction.

In addition to promoting densification and formation of contact, temperature can be used for producing crystallisation and improvement of ionic conductivity in lithium thiophosphates. In selecting the temperature and also the duration of heating, one needs to take into account the thermal stability of the materials involved. For example, the melting point of lithium metal is approximately 180° C., which means that, during the compaction and joining phase, the holding time at temperature of 180° C. should be limited such that exceeding the melting point of lithium metal does not cause damage to the anode. One way of limiting the rise of temperature of the lithium metal is to apply the heat with hot plate or hot roller from one direction only, i.e., from the side of the current collector of the cathode, and thereby control the temperature and duration of the thermal treatment for each of the material layers.

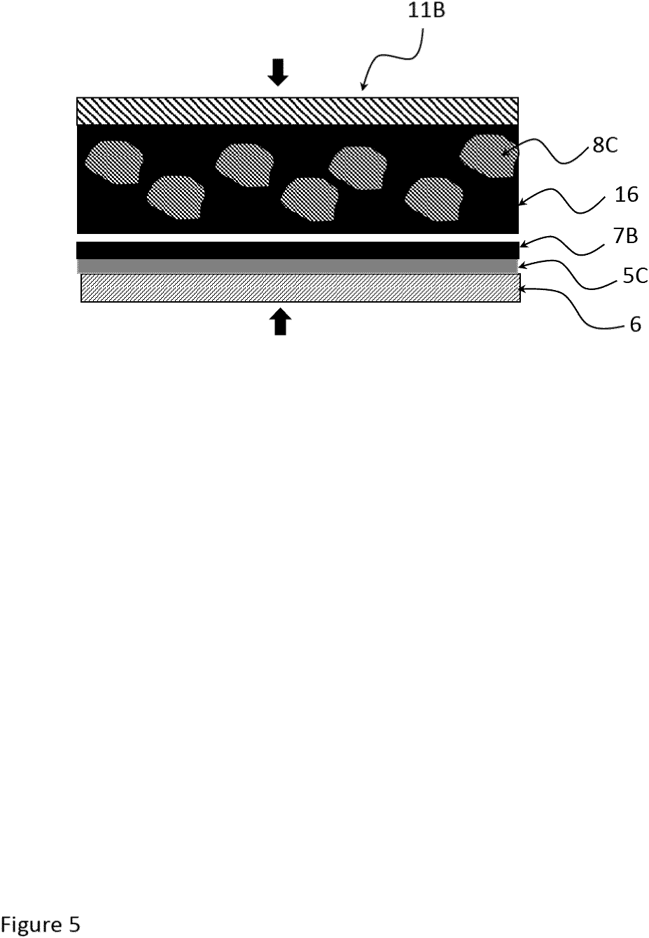

FIG. 5 represents joining the anode component (comprising material layers a current collector 6, a lithium-metal layer 5C, and an inorganic solid-electrolyte layer 7B) to the cathode component (comprising a current collector 11B as well as a mixture layer 16 formed by cathode-material particles 8C and inorganic solid electrolyte). In the presented joining process, the contact surfaces of both components are composed of inorganic solid electrolyte.

In the following, features of the invention are further compiled in a list-type form in the way of a summary.

The invention relates to a method for manufacturing a Li-ion battery containing lithium and solid inorganic electrolytes, the method comprising the steps of
Anode
   Producing a layer containing Li metal on the surface of a current collector made of metal, such as copper.
   Producing at least one inorganic material layer with sufficient ionic conductivity on the surface of the Li metal using a suitable deposition method such as CVD, PVD, ALD, or PLD.
Cathode
   Producing a mixture of cathode material and inorganic solid electrolyte as well as other possible constituents, such as components improving electrical conductivity (e.g., carbon); the mixture can be produced, for example, by mixing the selected powders in a suitable ratio and/or by coating cathode materials with inorganic solid electrolyte and other necessary materials.
   Compacting the mixture of cathode material, inorganic solid electrolyte, and other materials by means of pressure and/or temperature and joining it to a current collector made of metal, such as aluminium.
Joining the anode and the cathode together by means of pressure and/or temperature, such that the solid-electrolyte layers of the anode and the cathode form the contact surfaces. At the same time, the outcome of the joining and compaction phases performed at earlier processing steps can be completed and improved.

In an embodiment of the invention, a lithium battery, Li-ion battery, or Li-ion capacitor is further assembled in the method by using parts which comprise an anode composed of a copper current collector with a pulsed laser deposited lithium layer of 15 micrometers in thickness and pulsed laser deposited solid inorganic electrolyte LiPON, and a cathode composed of a mixture of NMC622 cathode particles and LPS solid electrolyte mixed in a ball mill, which mixture is hot pressed at 180° C. onto the surface of an aluminium current collector. The anode and the cathode are joined together by hot pressing at 180° C. such that a contact is formed between the LPS and LiPON contact surfaces.

In an embodiment of the invention, on the surface of a 10 micrometers thick layer of lithium metal deposited on a copper current collector, a solid-electrolyte layer of LLZO is deposited, which layer has a thickness of 0.2-1 micrometers.

In an embodiment of the invention, on the surface of a 10 micrometers thick layer of lithium metal deposited on a copper current collector, a solid-electrolyte layer of LLZO is deposited, which layer has a thickness of 0.2-1 micrometers, after which on top of the LLZO layer, a 0.5-5 micrometers thick layer of solid electrolyte LPS is deposited. This component is joined to a cathode by hot pressing, such that the countersurface of the contact is essentially composed of solid electrolyte LPS.

In an embodiment of the invention, on the surface of a 5 micrometers thick layer of lithium metal deposited on a copper current collector, a solid-electrolyte layer of LLZO with thickness of 500 nm is deposited by PLD method, which LLZO layer is at least 90% amorphous, and this component is joined to a cathode component.

In an embodiment of the invention, on the surface of a 10 micrometers thick layer of lithium metal deposited on a copper current collector, first a 10-nm thick Al₂O₃ layer is deposited by ALD method, on top of which layer a 3 micrometers thick LPS layer is deposited by PLD method, and this component is joined to a cathode component.

In an embodiment of the invention, NMC622 cathode-material particles with an average size of approximately 5 micrometers are coated with a LPS solid-electrolyte layer of 0.5 micrometers in thickness, and the coated powder particles are joined and compacted to adhere to an aluminium current collector by means of pressure at room temperature, and this component is joined to an anode component.

In an embodiment of the invention, the lithium-metal layer deposited by PLD method on the copper current collector of an anode has a thickness of 10 micrometers, and on the surface of the lithium-metal layer, a 0.5 micrometers thick solid-electrolyte layer of LLZO is deposited by PLD method, after which on top of the LLZO layer, a 4 micrometers thick layer of LPS is deposited by PLD method, which LPS layer functions as contact surface to a cathode.

In an embodiment of the invention, a mixture of NMC622 cathode-material particles, solid electrolyte LPS, and conducting carbon is joined and compacted to an aluminium foil by means of pressure and temperature such that the joining temperature is 280° C., and this cathode component is joined to an anode component.

In an embodiment of the invention, first, a 0.4 micrometers thick layer of lithium metal is added on copper current collector by PLD method. Thereafter, thermal evaporation is used for producing a 5 micrometers thick layer of lithium, on top of which a 2 micrometers thick layer of LLZO is produced by PLD method followed further by a 1 micrometer thick layer of LPS, and this component is joined to a cathode.

In an embodiment of the invention, on a copper current collector, a 5 micrometers thick lithium-metal layer is deposited by PLD, on top of the lithium metal a 1 micrometer thick layer of LiPON, and, finally, a 0.5 micrometers thick LGPS layer on top of the LiPON layer, and this component is joined to a cathode.

The method according to the invention has the following advantages:
i. Li-ion batteries based on lithium-metal anodes and having very good internal ionic conductivity can be produced basing completely on inorganic solid electrolyte
ii. Considerably higher energy density of Li-ion batteries can be achieved
iii. Resistance against growth of lithium-metal dendrites can be increased by utilising different types of inorganic solid electrolytes
iv. By utilising the best inorganic solid electrolytes, such as lithium thiophosphates (inter alia LPS), significantly better ionic conductivity than with polymer solid electrolytes can be achieved at room temperature
v. By combining several solid electrolytes, a combination of ionic conductivity, suppression of the growth of dendrites, and chemical stability can be achieved simultaneously
vi. By combining several different production methods for production of different material layers, good and reliable contact surfaces can be generated
vii. Combination of several different production methods enables good flexibility to improve the performance, safety, and cost efficiency of lithium-ion battery
viii. Good and reliable adhesion is achieved between different material layers without special adhesion layers or binders
ix. By utilising the best inorganic solid electrolytes and functional surfaces, the lifetime of batteries can be improved when compared to solutions using liquid or polymer electrolytes
x. It is possible to manufacture batteries with both a considerably higher gravimetric energy density and a considerably higher volumetric energy density when compared to the conventional material solutions

In the invention, it is possible to combine individual features of the invention mentioned above and in the dependent claims into new combinations, in which two or several individual features may have been included in the same embodiment.

The present invention is not limited only to the examples shown, but many variations are possible within the scope of protection defined by the enclosed claims.

1. A method for producing an electrochemical energy storage device comprising lithium and inorganic solid-electrolyte material, the method comprising:
a method for depositing lithium metal on the surface of a metal current collector in production of an anode component;
depositing at least one inorganic solid electrolyte on the surface of lithium metal in the production of the anode component;
depositing a mixture comprising inorganic solid electrolyte, a component improving electrical conductivity, and cathode material on metal current collector in the production of a cathode component;
wherein:
the cathode component and the anode component are produced as separate components;
the lithium-metal layer of the anode component is produced at least partly by PLD method on the metal current collector,
at least one inorganic solid-electrolyte layer is produced by utilising a deposition method on the lithium-metal layer of the anode components
the contact surfaces of the cathode and anode components comprise inorganic solid electrolyte;
the cathode and anode components are joined together by contact surfaces by pressure and/or temperature;
the electrochemical energy storage device comprises lithium thiophosphate at least 80% of a total amount of the solid electrolyte.

2. The method according to claim 1, wherein the lithium-metal layer deposited on the current collector of the anode component is 30 micrometers thick at most.

3. The method according to claim 1, wherein the lithium-metal layer has been produced at least in two phases, and a first layer is at most 5 micrometers in thickness and produced by PLD method.

4. The method according to claim 1, wherein on the surface of the lithium-metal layer, a coating has been produced of at least one inorganic material having a thickness of 50 micrometers at most.

5. The method according to claim 1, wherein on the surface of the lithium-metal layer a coating has been produced of two or more inorganic materials, such that at most one material is not an ionically conductive material.

6. The method according to claim 1, wherein on the surface of the lithium-metal layer an inorganic coating has been produced, such that at least one material layer is an inorganic solid electrolyte lithium thiophosphate which comprises at least sulfur, phosphorus, and lithium.

7. The method according to claim 1, wherein, first, on the surface of the current collector of the anode, at most 30 micrometers thick lithium-metal layer is produced, on top of the lithium-metal layer at least 10-nm thick layer of an inorganic material is added, after which is added at least 200-nm thick layer of lithium thiophosphate which comprises at least sulfur, phosphorus, and lithium.

8. The method according to claim 1, wherein the cathode material is produced from a mixture of inorganic solid electrolyte, components improving electrical conductivity, and cathode particles in which mixture the solid electrolyte comprises at least 80% of lithium thiophosphate which comprises at least sulfur, phosphorus, and lithium.

9. The method according to claim 1, wherein on the surface of the cathode particles, an inorganic material layer with a thickness of 100 nm at most is coated with a deposition method.

10. The method according to claim 1,wherein a mixture of inorganic solid electrolyte, components improving electrical conductivity, cathode particles and other constituents is processed by pressure and/or temperature to increase the density of the structure, to improve adherence to the current collector and to modify the microstructure.

11. The method according to claim 10, wherein the temperature applied is at least 150° C.

12. The method according to claim 11 , wherein the temperature applied together with the pressure is at least 150° C. but at most 300° C.

13. The method according to claim 1, wherein the solid-electrolyte layer which does not contain cathode-material particles and is located between the anode and cathode layers has thickness of at least 2 micrometers and at most 100 micrometers.

14. The method according to claim 1, wherein in the method, a lithium battery, a Li-ion battery, or a Li-ion capacitor is assembled utilising material layers comprising anode, cathode, and solid electrolyte such that at least one layer comprising lithium is produced by laser ablation deposition.

15. (canceled)

16. An electrochemical energy storage device utilising lithium, the device comprising:
a. a cathode material; and
b. an anode material;
c. lithium metal deposited on a surface of a metal current collector in production of the anode component;
d. at least one inorganic solid electrolyte deposited on the surface of the lithium metal in the production of the anode component;
e. a mixture comprising inorganic solid electrolyte, a component improving electrical conductivity, and the cathode material deposited on a metal current collector in production of a cathode component;
f. lithium thiophosphate at least 80% of the total amount of the solid electrolyte;
g. the lithium-metal anode component, production of which use of PLD method at least in one production phase;
h. contact surfaces of the cathode and anode components comprising inorganic solid electrolyte; and
i. wherein the anode component and the cathode component are joined together by contact surfaces by pressure and/or temperature.
